(19) United States
(12) Patent Application Publication
(10) Pub. No.: US 2019/0006569 A1
(43) Pub. Date: Jan. 3, 2019

(54) LED FRAME, MANUFACTURE METHOD THEREOF AND LED DEVICE

(71) Applicant: Shenzhen Refond Optoelectronics Co., LTD, Shenzhen (CN)

(72) Inventor: Zhi You, Shenzhen (CN)

(21) Appl. No.: 15/722,763

(22) Filed: Oct. 2, 2017

(30) Foreign Application Priority Data
Jun. 30, 2017 (CN) 201710521348.9

(51) Int. Cl. H01L 33/62; H01L 33/56; H01L 33/48

(52) U.S. Cl. CPC H01L 33/62; H01L 33/486; H01L 33/56

(57) ABSTRACT

An LED frame, a manufacture method thereof and an LED device are disclosed. A transparent insulating protection layer is prepared on the metal material layer of the surface of the LED frame by a process such as vapor deposition, sputtering, vacuum plating, etc., so that the metal material layer can be prevented from making contact with the external environment. The transparent insulating protection layer is a transparent inorganic material layer and the metal material layer is a silver layer or an aluminum layer.

### CROSS-REFERENCE TO RELATED APPLICATION

This application is based on and claims the benefit of priority from Chinese Patent Application No. 201710521348.9, filed on Jun. 30, 2017, the contents of which are incorporated by reference.

### FIELD

The invention relates to the field of LEDs, and in particular to an LED frame and a manufacture method thereof, as well as an LED device.

### BACKGROUND

The surface of the LED frame is mostly covered with a metal material layer, which is generally subjected to silver plating or aluminum plating to improve the luminous efficiency of the product and facilitate the bonding of leads. However, the silver layer and the aluminum layer are chemically reactive and thus are easy to be oxidized or react with other contaminants such as halogen, etc., causing discoloration of the LED frame, and thereby affecting the luminous efficiency and the service life of LED products. As a result, it is impossible to use the silver-plated or aluminum-plated LED products in many circumstances such as outdoors and automobiles, etc., which have strict requirements on the use conditions of the LED products.

At present, the performance of the LED products is generally improved by covering a polymeric organic material coating on the metal material layer or the packaging device. However, the coating material may greatly affect the properties such as initial luminous efficiency, etc., as well as the long-term reliability of the LED products, and therefore there is a need to provide an LED product which will not cause loss of light energy and can avoid contamination of the metal material layer.

### SUMMARY

The invention aims to solve the technical problem that existing LED products have low luminous efficiency and the metal material layer is easy to be contaminated. The technical solutions are described below.

In an aspect of the invention, it provides an LED frame having a body onto which a metal material layer is covered, the metal material layer is covered with a transparent insulating protection layer.

Preferably, the transparent insulating protection layer is a transparent inorganic material layer. Generally, in the process of preparing the transparent inorganic material layer, organic materials will be inevitably mixed into the transparent inorganic material layer. The transparent insulating protection layer consists of a transparent inorganic material having excellent reliability and is covered on the surface of the metal material layer. After encapsulated with an encapsulating adhesive, it is internally encapsulated and will not be peeled off due to mechanical friction.

Preferably, the transparent insulating protection layer is a silicon dioxide layer or an aluminium oxide layer.

Preferably, the transparent insulating protection layer has a thickness of 0.01 μm-50 μm.

Preferably, the transparent insulating protection layer is characterized by having a transmittance ≥50%.

Preferably, the metal material layer is a silver layer or an aluminum layer. The metal material layer is made of a metal material having high reflectivity such as silver or aluminum.

In another aspect of the invention, it provides a method for manufacturing an LED frame as described above, including the following steps: (1) preparing a metal material layer on the LED frame body; and (2) preparing a transparent insulating protection layer on the metal material layer.

The metal material layer can be prepared on the LED frame body by electroplating, electroless plating or metal slurry sintering.

Preferably, the preparation of the transparent insulating protection layer is conducted by any process of vapor deposition, sputtering and vacuum plating.

In yet another aspect of the invention, it provides an LED device comprising the frame as described above.

The beneficial effects of the invention are as follows. The LED frame and LED device are manufactured, by preparing a dense transparent insulating protection layer on the surface of the LED frame, the metal material layer on the surface of the frame is prevented from making contact with the external environment, and thus an effect of protecting the metal material layer can be achieved. Meanwhile, the transparent insulating protection layer will not cause loss of light energy and has good luminous efficiency and performance.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 shows an LED frame according to the 1st embodiment;

FIG. 2 shows an LED device according to the 2nd embodiment; and

FIG. 3 shows an LED device according to the 3rd embodiment.

### DETAILED DESCRIPTION

The following description is merely exemplary in nature and is not intended to limit the present disclosure, application, or uses.

The conception, specific structure and technical effects generated of the invention will be clearly and completely described below in combination with the embodiments and the accompanying drawings to enable a full understanding of the objectives, features and effects of the invention. The described embodiments are only a part, but not all embodiments of the invention, and other embodiments obtained by those skilled in the art without creative work based on the embodiments of the invention should all fall within the protection scope of the invention.

### Embodiment 1

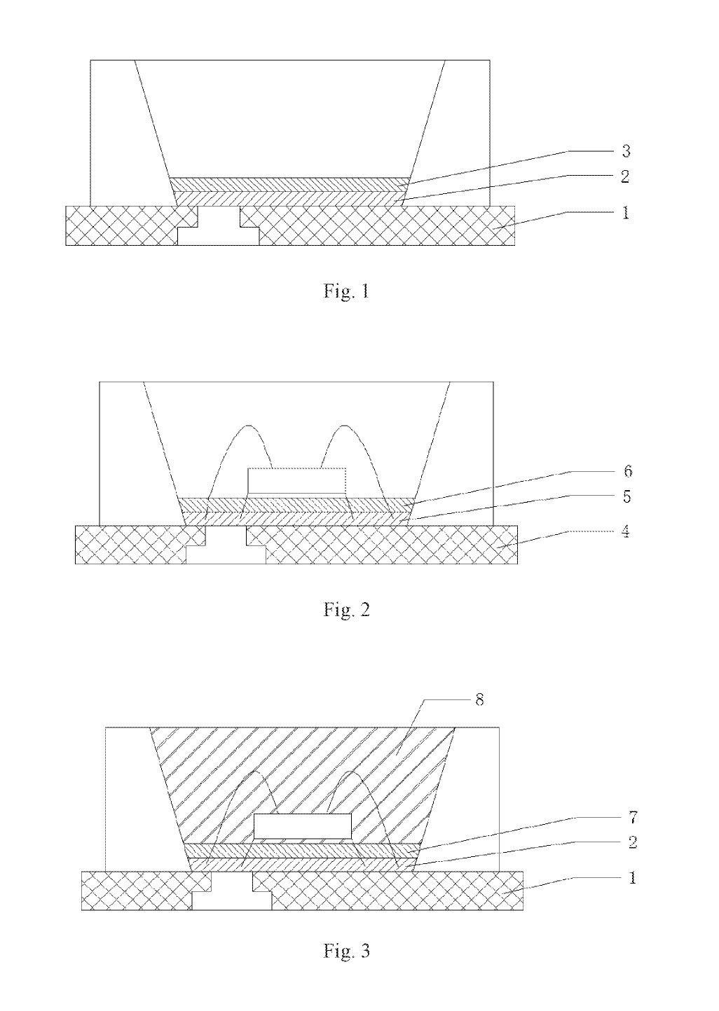

In the 1st embodiment, an LED frame is provided as shown in FIG. 1. A metal material layer I 2 is electroplated on the substrate I 1 of the LED frame body, and then a transparent insulating protection layer I 3 is prepared on the metal material layer I 2 by vapor deposition process. The substrate I 1 of the LED frame body is copper, the metal material layer I 2 is a silver layer. The transparent insulating protection layer I 3 includes SiOx (x=1, 2, 3, 4 . . . ), and/or SiyNz (y=1, 2, 3, 4 . . . ; z=1, 2, 3, 4 . . . ). Preferably, the transparent insulating protection layer I 3 is a silicon dioxide layer, and the transparent insulating protection layer I 3 has a thickness of 0.01 μm and a transmittance of 93%.

The substrate of the frame body is exemplified by copper in this embodiment to set forth the conception of the disclosure, and the substrate of the frame body can be made of metal, ceramic, glass or fiberboard, etc.

### Embodiment 2

In the 2nd embodiment, an LED device is provided as shown in FIG. 2. A metal material layer II 5 is plated on the substrate II 4 of the LED frame body by way of electroless plating, and then a transparent insulating protection layer II 6 is prepared on the metal material layer II 5 by sputtering process. The substrate II 4 of the LED frame body is glass, the metal material layer II 5 is an aluminum layer, the transparent insulating protection layer II 6 is an aluminium oxide layer, and the transparent insulating protection layer II 6 has a thickness of 50 μm and a transmittance of 50%.

### Embodiment 3

In the 3rd embodiment, an LED device is provided as shown in FIG. 3. A metal material layer I 2 is covered on the substrate I 1 of the LED frame body by the metal slurry sintering process, a transparent insulating protection layer III 7 is prepared on the metal material layer I 2 by vacuum plating process, and then a layer of encapsulating adhesive 8 is coated on the transparent insulating protection layer III 7. The substrate 1 of the LED frame body is copper, the metal material layer I 2 is an aluminum layer. The transparent insulating protection layer III 7 includes SiOx (x=1, 2, 3, 4 . . . ), and/or SiyNz (y=1, 2, 3, 4 . . . ; z=1, 2, 3, 4 . . . ). Preferably, the transparent insulating protection layer III 7 is a silicon dioxide layer, and the transparent insulating protection layer III 7 has a thickness of 25 μm and a transmittance of 84%.

The disclosure has described certain preferred embodiments and modifications thereto. Further modifications and alterations may occur to others upon reading and understanding the specification. Therefore, it is intended that the disclosure not be limited to the particular embodiment(s) disclosed as the best mode contemplated for carrying out this disclosure, but that the disclosure will include all embodiments falling within the scope of the appended claims.

1. An LED frame, comprising a body onto which a metal material layer is covered, wherein the metal material layer is covered with a transparent insulating protection layer.

2. The LED frame according to claim 1, wherein the transparent insulating protection layer is a transparent inorganic material layer.

3. The LED frame according to claim 1, wherein the transparent insulating protection layer is a silicon dioxide layer or an aluminium oxide layer.

4. The LED frame according to claim 1, wherein the transparent insulating protection layer has a thickness of 0.01 μm-50 μm.

5. The LED frame according to claim 1, wherein the transparent insulating protection layer has a transmittance ≥50%.

6. The LED frame according to claim 1, wherein the metal material layer is a silver layer or an aluminum layer.

7. A method for manufacturing an LED frame having a frame body, the method comprising the following steps:
preparing a metal material layer on the frame body; and
preparing a transparent insulating protection layer on the metal material layer.

8. The method according to claim 7, wherein the preparation of the transparent insulating protection layer is conducted by a process from a group including vapor deposition, sputtering and vacuum plating.

9. The method according to claim 7, wherein the transparent insulating protection layer is a transparent inorganic material layer.

10. The method according to claim 7, wherein the transparent insulating protection layer is a silicon dioxide layer or an aluminium oxide layer.

11. The method according to claim 7, wherein the transparent insulating protection layer has a thickness of 0.01 μm-50 μm.

12. The method according to claim 7, wherein the transparent insulating protection layer has a transmittance ≥50%.

13. The method according to claim 7, wherein the metal material layer is a silver layer or an aluminum layer.

14. An LED device, comprising the frame comprising a body onto which a metal material layer is covered, wherein the metal material layer is covered with a transparent insulating protection layer.

15. The LED device according to claim 14, wherein the transparent insulating protection layer is a transparent inorganic material layer.

16. The LED device according to claim 14, wherein the transparent insulating protection layer is a silicon dioxide layer or an aluminium oxide layer.

17. The LED device according to claim 14, wherein the transparent insulating protection layer has a thickness of 0.01 μm-50 μm.

18. The LED device according to claim 14, wherein the transparent insulating protection layer has a transmittance ≥50%.

19. The LED device according to claim 14, wherein the metal material layer is a silver layer or an aluminum layer.
